(19) United States
(12) Patent Application Publication
(10) Pub. No.: US 2015/0162269 A1
(43) Pub. Date: Jun. 11, 2015

(54) SEMICONDUCTOR DIE PACKAGE WITH INSULATED WIRES FOR ROUTING POWER SIGNALS

(71) Applicant: Wai Yew Lo, Petaling Jaya (MY)

(72) Inventor: Wai Yew Lo, Petaling Jaya (MY)

(21) Appl. No.: 14/098,560

(22) Filed: Dec. 6, 2013

(51) Int. Cl. H01L 23/495; H01L 21/56; H01L 23/50; H01L 23/31; H01L 23/00

(52) U.S. Cl. CPC H01L 23/4951; H01L 23/3114; H01L 24/49; H01L 24/85; H01L 23/50; H01L 21/56; H01L 2224/48177; H01L 2224/85345

(57) ABSTRACT

A semiconductor die package has a die mounted to a die pad. The die has data bond pads and power supply bond pads. Lead fingers are spaced from and project outwardly from the die pad. Each of the lead fingers has a proximal end that is near to a respective edge of the die pad, and a distal end farther from the die pad. The lead fingers include power bar lead fingers and data lead fingers. A power bar bridges the proximal ends of two of the power bar lead fingers. The power bar is between the proximal ends of the data lead fingers and the respective edge of the die pad. Insulated bond wires are used to selectively electrically couple the power bar to the die power supply bond pads.

### BACKGROUND OF THE INVENTION

The present invention relates generally to semiconductor packaging and, more particularly, to a semiconductor die package that uses insulated wires to route power signals.

Semiconductor die packages are typically formed with a semiconductor die mounted on a flag or die pad of a lead frame. External connectors in the form of leads of the lead frame are electrically coupled, with bond wires, to die bonding pads on the die. After the bonding pads and leads are coupled with the bond wires, the die and bond wires are encapsulated with a plastic mold compound leaving sections of the leads exposed. End regions (pins) of the lead fingers either project outwardly from the mold compound or are at least flush with the compound so they can be used as terminals, allowing the semiconductor package to be electrically connected directly to other devices or to a printed circuit board (PCB).

Semiconductor dies often have increased functionality and thus the number of external connectors (pin count) consequently must be increased to accommodate the additional input/output signal pads and power supply pads of the semiconductor die. This increase in the number of external connection pads typically results in a size increase of the semiconductor die package (footprint) and the requirement of additional bond wires.

The number of power supply bond wires required to couple the power supply pads (both power and ground) to the die power pads may account for a large proportion of the bond wires. These power supply bond wires can be as high as 50% of all the bond wires and thus specific power supply bars on the lead frame are located adjacent the edges of the lead frame flag. However, these specific power supply bars require support and external connections from lead frame leads. It would be advantageous to use fewer leads to supply power to the semiconductor die.

### BRIEF DESCRIPTION OF THE DRAWINGS

The invention, together with objects and advantages thereof, may best be understood by reference to the following description of preferred embodiments together with the accompanying drawings in which:

FIG. 1 is a top plan view of a conventional lead frame and die assembly;

FIG. 2 is a top plan view of a lead frame in accordance with a preferred embodiment of the present invention;

FIG. 3 is a top plan view of a lead frame and die assembly formed from the lead frame of FIG. 1 in accordance with a preferred embodiment of the present invention;

FIG. 4 is a cross-sectional side view through 3-3′ of the assembly of FIG. 3;

FIG. 5 is a top plan view of a wire bonded lead frame and die assembly formed from the assembly of FIG. 3 in accordance with a first preferred embodiment of the present invention;

FIG. 6 is a side view of a semiconductor die package formed from the assembly of FIG. 5 in accordance with a preferred embodiment of the present invention;

FIG. 7 is a top plan view of a wire bonded lead frame and die assembly in accordance with a second preferred embodiment of the present invention;

FIG. 8 is a top plan view of a wire bonded lead frame and die assembly in accordance with a third preferred embodiment of the present invention;

FIG. 9 is a top plan view of a wire bonded lead frame and die assembly in accordance with a fourth preferred embodiment of the present invention; and

FIG. 10 is a flow chart illustrating a method of assembling a semiconductor die package in accordance with a preferred embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides a semiconductor die package that includes a die pad and a semiconductor die mounted to the die pad. The semiconductor die has a die support mounting surface attached to the die pad and an opposite active surface associated with both die connection data pads and die connection power supply pads. A plurality of lead fingers is spaced from and project outwardly from the die pad. Each of the lead fingers has a proximal end that is proximal to a respective edge of the die pad, and a distal end farther from the die pad. The lead fingers include power bar lead fingers and data carrying lead fingers. A power bar bridges the proximal ends of two of the power bar lead fingers. The power bar is located between the proximal ends of a group of the data carrying lead fingers and the respective edge of the die pad. Insulated bond wires are used to selectively electrically couple the power bar to a plurality of the die connection power supply pads.

In another embodiment, the present invention provides a method of assembling a semiconductor die package. The method comprises providing a lead frame that has an outer frame enclosing a centrally located a die pad and tie bars extending from the outer frame and supporting the die pad. The lead frame also has a plurality of lead fingers extending from the outer frame towards the die pad. Each of the lead fingers has a proximal end that is near to a respective edge of the die pad and a distal end integral with the outer frame. The lead fingers include power bar lead fingers and data carrying lead fingers. A power bar bridges the proximal ends of two of the power bar lead fingers so that the power bar is located between the proximal ends of a group of the data carrying lead fingers and a respective edge of the die pad. The method also includes mounting a semiconductor die to the die pad. The semiconductor die has a die support mounting surface attached to the die pad, and an opposite active surface associated with both die data pads and die power supply pads. The method further includes selectively electrically coupling the power bar to a plurality of the die power supply pads with insulated bond wires.

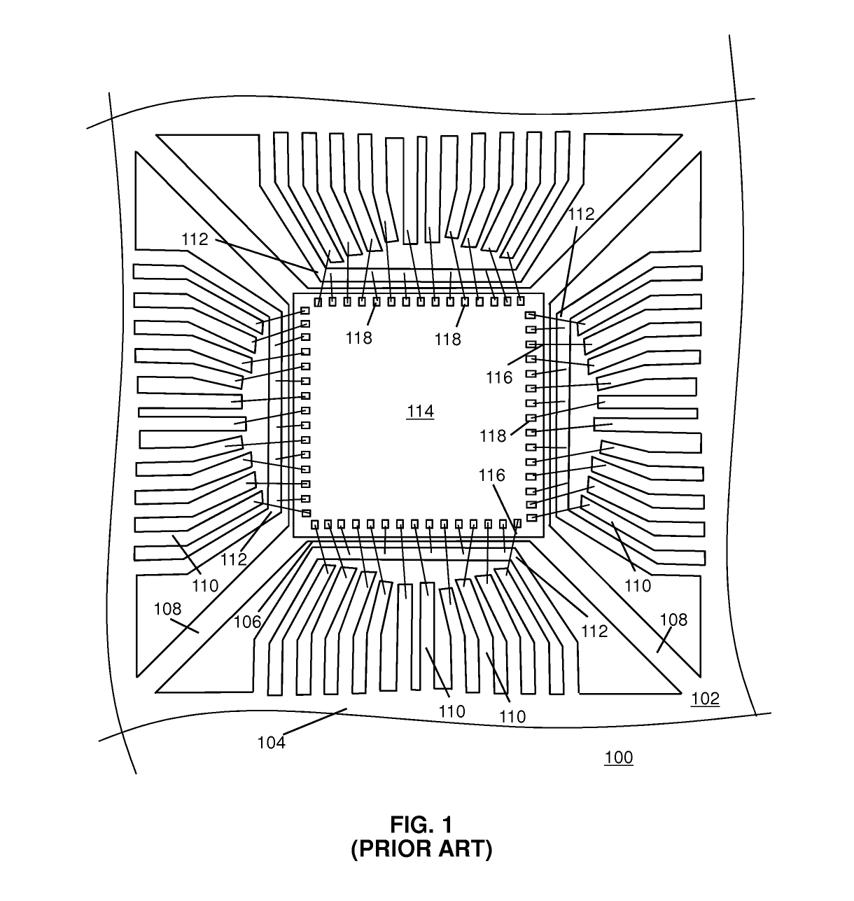

Referring now to FIG. 1, a top plan view of a conventional lead frame and die assembly 100 is shown. The assembly includes a lead frame 102 with an outer frame 104, die pad 106, tie bars 108, lead fingers 110 and power bars 112. A semiconductor die 114 is mounted to the die pad 106 and bond wires 116 selectively couple bonding pads 118 of the die 114 to ends of the lead fingers 110 or the power bars 112. More specifically, each of the power bars 112 are coupled only to die bonding pads that are located along the same edge of the die pad 106. This configuration requires at least eight lead fingers to be used for supplying a positive supply to a completed packaged formed from the assembly.

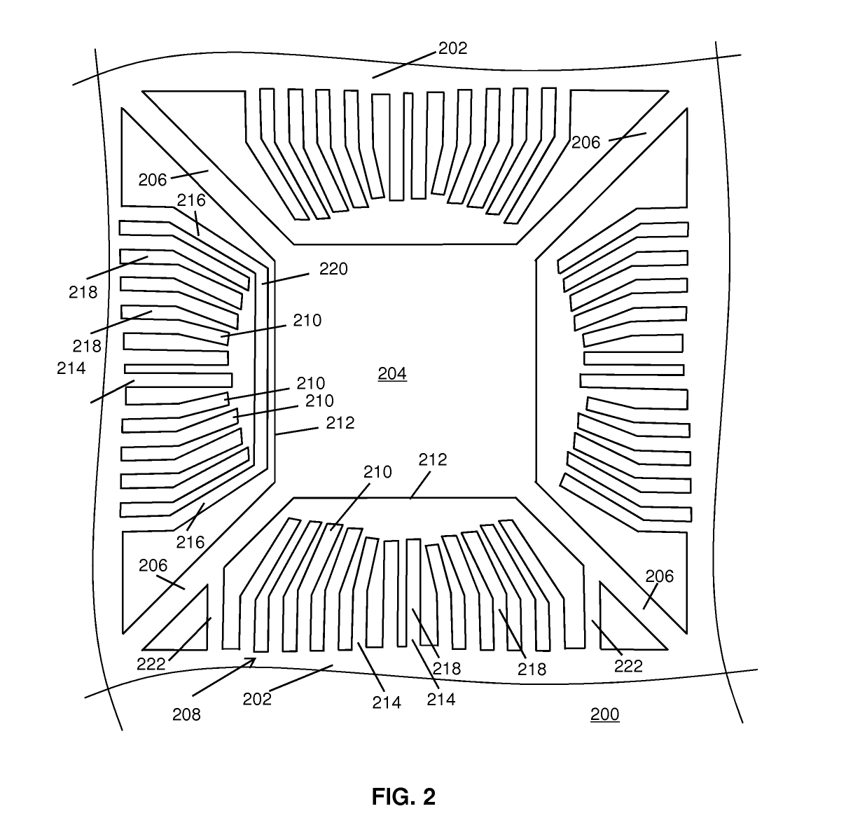

FIG. 2 is a top plan view of a lead frame 200 in accordance with a preferred embodiment of the present invention. The lead frame 200 has an outer frame 202 enclosing a centrally located a die pad 204 sometimes referred to as a die paddle or flag. Tie bars 206 extend inwards from the outer frame 202 and support the die pad 204, and lead fingers 208 extend inwardly from the outer frame 202 towards the die pad 204. Each of the lead fingers 208 has both a proximal end 210 that is near to a respective edge 212 of the die pad 202 and a distal end 214 farther from the die pad 202 and integral with the outer frame 202. The lead fingers 208 include power bar lead fingers 216 and data carrying lead fingers 218. Furthermore, a power bar 220 bridges the proximal ends 210 of two of the power bar lead fingers 216 so that the power bar 220 is located between the proximal ends of a group of the data carrying lead fingers 218 and a respective edge of the die pad 212. Also, in this embodiment, there is only one power bar 220 and the power bar 220 extends along only one side of the die pad 204. As shown, the tie bars 206 extend from corner regions of the die pad 204 and one or more of the tie bars have an extending lead 222 for providing an external ground connection.

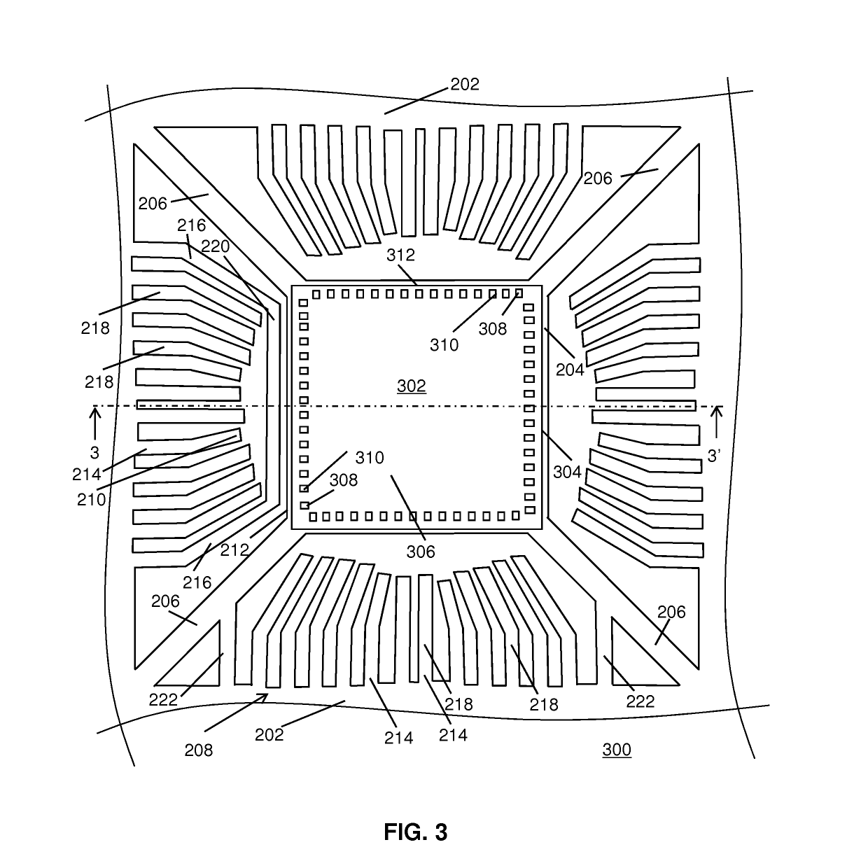

FIG. 3 is a top plan view of a lead frame and die assembly 300 formed from the lead frame 200 in accordance with a preferred embodiment of the present invention. The assembly 300 includes a semiconductor die 302 mounted to the die pad 204. The die 302 has a back side 304 attached to the die pad 204, and an opposite, top active surface 306 that has both die data bonding pads 308 and die power supply bonding pads 310. The die data bonding pads 308 and die power supply bonding pads 310 are located along all four edges 312 of the semiconductor die 302.

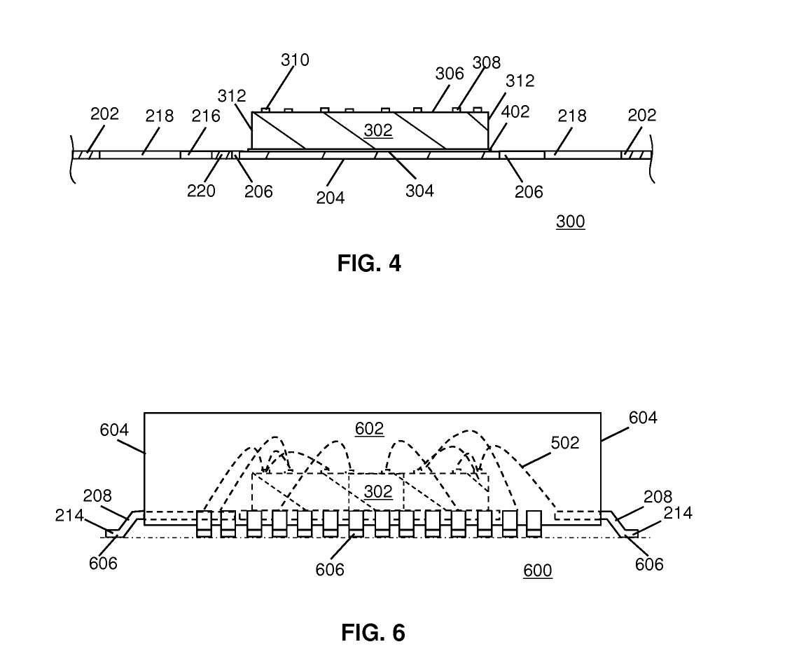

FIG. 4 is a cross-sectional side view through 3-3′ of the assembly 300. In this illustration the die back side 304 is shown attached to the die pad 204 with an epoxy 402. However, other forms of bonding the die back side 304 to the die pad 204 may be used as will be apparent to a person skilled in the art.

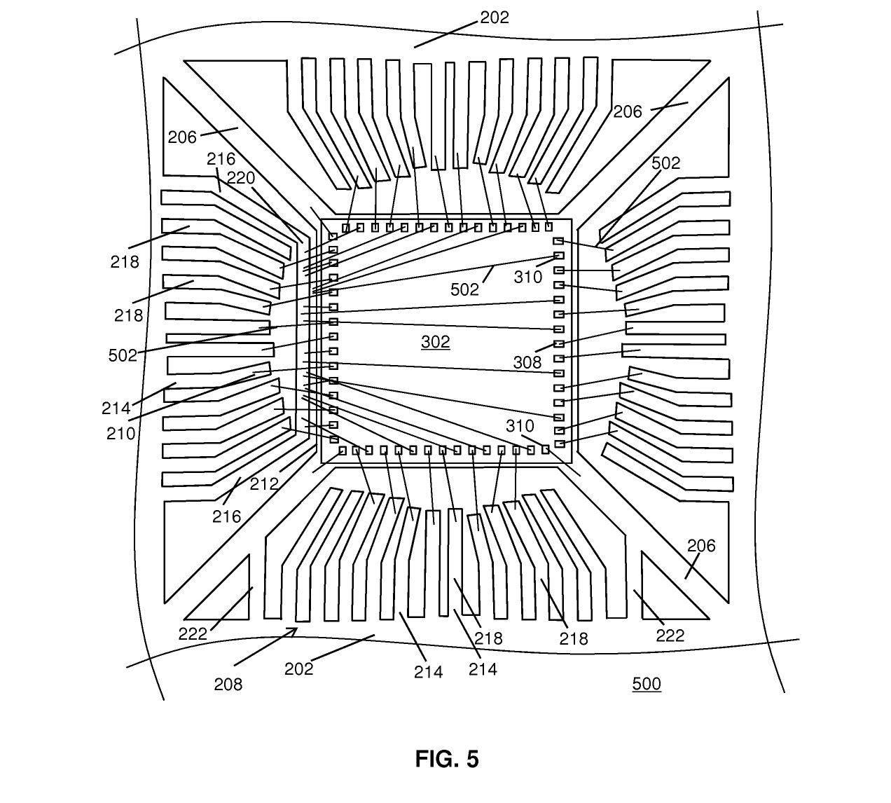

FIG. 5 is a top plan view of a wire bonded lead frame and die assembly 500 formed from the assembly 300 in accordance with a first preferred embodiment of the present invention. In this embodiment, the power bar 220 is coupled to the die power bonding pads 310 with insulated bond wires 502. In one embodiment of the present invention, the die data carrying bond pads 308 are connected to the data carrying lead fingers 218 with non-insulated bond wires. That is, since the power bar 216 is located on only one side of the die 302, insulated bond wires 502 are used because some of the insulated wires 502 extend across the die 302 and cross other bond wires. Therefore, the use of insulated bond wires prevents shorts. In one embodiment of the invention, insulated bond wires also are used to connect the die data bonding pads 308 with the data carrying lead fingers 218. However, that is not a requirement and thus, in another embodiment of the invention, regular non-insulated bond wires are used to connect the die data bonding pads 308 with the data carrying lead fingers 218. Further, the insulated bond wires 502 also selectively electrically couple the tie bars 206 to the die power bond pads 310 (ground pads). Typically, the insulated bond wires 502 have an electrically conductive metal based core such as Gold, Copper or Silver coated with an insulating organic sheath. However, insulated bond wires 502 may be formed with other metals and insulating (non-electrically conductive) sheaths.

The process of wire bonding may be performed with a roughened capillary tip. When an end of the insulated bond wire 502 is placed in position for bonding (e.g., between the roughened capillary tip and surface of the power bar 220), the capillary tip vibrates thus tearing an insulated sheath at a region covering the end of the insulated bond wire 502. Once the sheath is torn wire bonding is performed in a conventional manner as will be apparent to a person skilled in the art. As illustrated in this embodiment, the insulated bond wires 502 selectively electrically couple the power bar 220 to the die power supply bond pads 310 located along all four edges 312 of the semiconductor die 302. Thus, only two lead fingers 208 are used for the positive rail power bar external connections, which frees up more lead fingers 208 for use as data carrying lead fingers.

Referring now to FIG. 6, a side view of a semiconductor die package 600 formed from the assembly 500 in accordance with a preferred embodiment of the present invention is illustrated. The semiconductor die package 600 includes an encapsulating material 602 covering the semiconductor die 302 and insulated bond wires 502 (and non-insulated bond wires if used for the data connections). The semiconductor die package 600 is formed after the encapsulating material 602 has been moulded to the lead frame 200 and a cutting or singulation process has removed the outer frame 202. As shown, the encapsulating material 602 forms a substantially rectangular housing with edges 604 from which the distal ends 214 of the lead fingers 208 protrude. The distal ends 214 may be trimmed and formed, such as by bending to form mounting feet 606, which provide for mounting and electrically connecting the package 600 to circuit boards and the like.

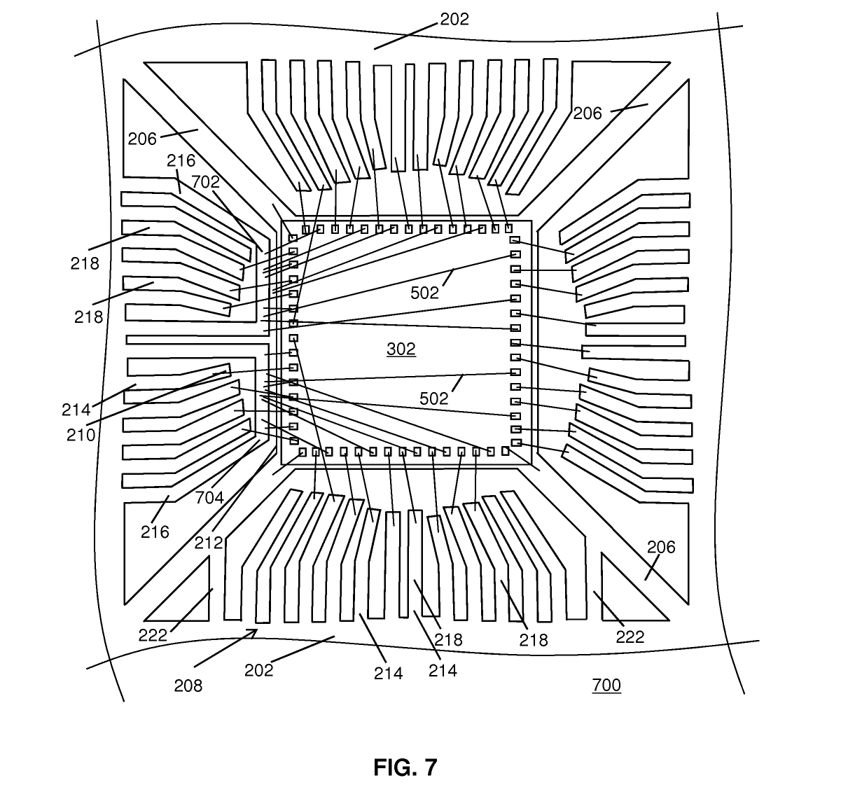

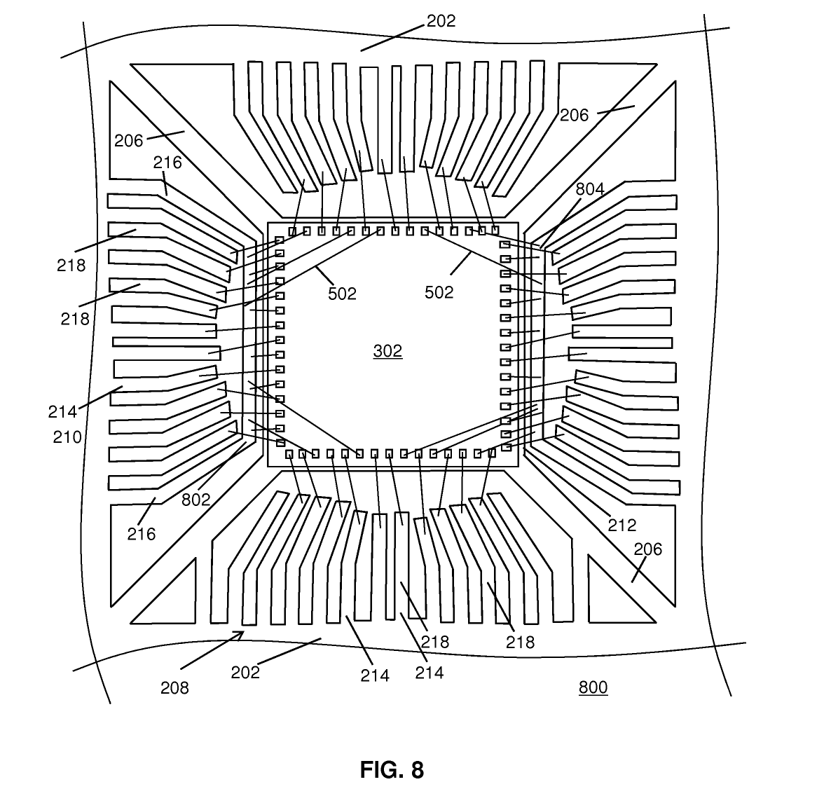

Referring to FIG. 7, a plan view of a wire bonded lead frame and die assembly 700 in accordance with second preferred embodiment of the present invention is shown. The assembly 700 is similar to the assembly 500 and therefore to avoid repetition only the differences will be described. The assembly 700 includes a first power bar 702 and a second power bar 704 located adjacent the same respective edge 212 of the die pad 204. The insulated bond wires 502 selectively electrically couple the first power bar 702 to the die power supply bond pads 310 of a first power rating, and the insulated bond wires 502 selectively electrically couple the second power bar 704 to the the die power supply bonding pads 310 of a another power rating. After an encapsulating material has been moulded to the assembly 700, singulation and trim and form processes may be performed to remove the outer frame 202 and shape the exposed lead fingers, which results in a semiconductor die package similar to the package 600. In this embodiment only two lead fingers 208 are used for external connections of each positive rail power bar 702, 704, which frees up more lead fingers 208 for use as data carrying lead fingers.

Referring to FIG. 8, a top plan view of a wire bonded lead frame and die assembly 800 in accordance with a third preferred embodiment of the present invention is shown. The assembly 800 is similar to the assembly 500 and therefore to avoid repetition only the differences will be described. The assembly 800 includes first and second power bars 802 and 804 located adjacent different respective edges 212 of the die pad 204. The insulated bond wires 502 selectively electrically couple the first power bar 802 to the die power supply bonding pads 310 of a first power rating, and the insulated bond wires 502 selectively electrically couple the second power bar 804 to the die power supply bonding pads 310 of a another power rating. After an encapsulating material has been moulded to the assembly 800, singulation and trim and form processes are performed to remove the outer frame 202 and shape the exposed portions of the lead fingers, which results in a semiconductor die package similar to the package 600. In this embodiment only two lead fingers 208 are used for external connections of each positive rail power bar 802, 804, which frees up more lead fingers 208 for use as data carrying lead fingers.

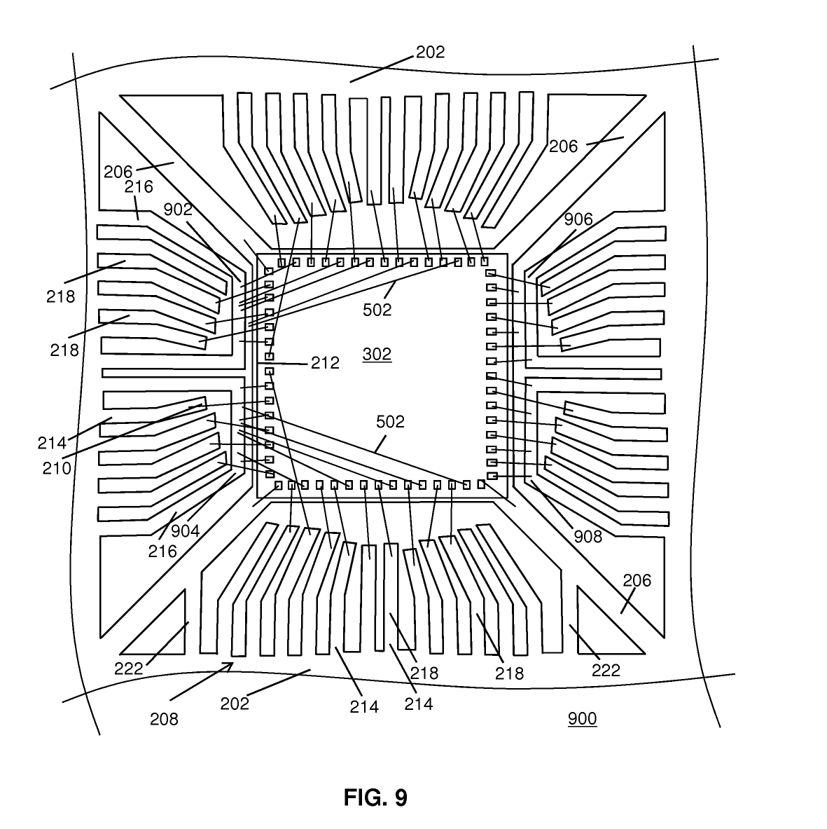

Referring to FIG. 9 there is illustrated a top plan view of a wire bonded lead frame and die assembly 900 in accordance with a fourth preferred embodiment of the present invention. The assembly 800 is similar to the assembly 500 and therefore to avoid repetition only the differences will be described. The assembly 800 includes first and second power bars 902, 904 located adjacent a first respective edge 212 of the die pad 204, and third and fourth power bars 906, 908 located adjacent another respective edge 212 of the die pad 204. The insulated bond wires 502 selectively electrically couple the first power bar 902 to the die power supply bonding pads 310 of a first power rating, the second power bar 904 to the die power supply bonding pads 310 of a second power rating, the third power bar 906 to the die power supply bonding pads 310 of a third power rating, and the fourth power bar 908 to the die power supply bonding pads 310 of a fourth power rating. After an encapsulating material has been moulded to the assembly 900, singulation and trim and form processes are performed to remove the outer frame 202 and shaped the exposed portions of the lead fingers, which results in a semiconductor die package similar to the package 600. In this embodiment, only two lead fingers 208 are used for external connections of each positive rail power bar 902,904,906,908, which frees up more lead fingers 208 for use as data carrying lead fingers.

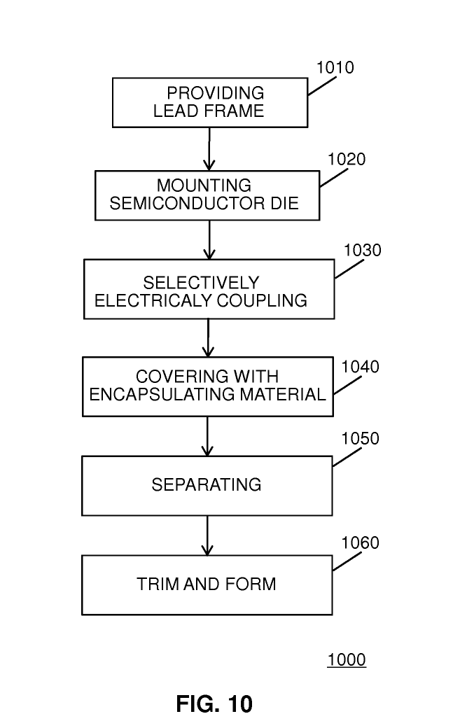

Referring to FIG. 10, a flow chart illustrating a method 1000 of manufacturing a semiconductor die package in accordance with a preferred embodiment of the present invention is shown. For explanation purposes only, the method 1000 will be described with reference to the assembly of the semiconductor die package 600. The method 1000, at a providing step 1010, provides the lead frame 200 and at a mounting step 1020 the semiconductor die 302 is mounted to the die pad 204 with the epoxy 402. At step 1030, the power bar 220 is selectively electrically coupled to the die power supply bonding pads 310 with the insulated bond wires 502. The die data bonding pads 308 are also selectively coupled to the data carrying lead fingers 218 with the insulated bond wires 502. In addition, the tie bars 206 are selectively electrically coupled to the die bonding pads with the insulated bond wires 502. Note that if only the die power supply bonding pads are coupled to the power bar with insulated wires and the die data bonding pads are coupled to the data carrying lead fingers with non-insulated bond wires, then it is preferable to do two passes of the wire bonding process, a first pass for the insulated wires and a second pass for the non-insulated wires.

At a covering step 1040, the semiconductor die 302 and insulated bond wires 502 are covered with and encapsulating material 602. Next, at a separating step 1050, the tie bars and lead fingers are separated from the outer frame 202 using a punching or cutting process. A trim and forming process, at step 1060, completes the assembly of the semiconductor die package 600 when the distal ends 214 of the lead fingers 208 are bent to form the mounting feet 606.

As will be apparent to a person skilled in the art, other semiconductor packages can be formed by the method such as packages formed from the wire bonded lead frame and die assemblies 700, 800 and 900. Advantageously, the present invention provides for increased data pin count allocation for a semiconductor die since the die power supply connection pads 310 on any edge of the die can be coupled to a selected power bar. In addition, the insulated bond wires 502 alleviate potential shorts between such bond wires that cross each other to provide selective coupling to the power bar or bars.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A semiconductor die package, comprising:
a die pad;
a semiconductor die mounted to the die pad, the semiconductor die having a die support mounting surface attached to the die pad and an opposite, active surface having both data bonding pads and power supply bonding pads;
a plurality of lead fingers spaced from and projecting outwardly from the die pad, each of the lead fingers having a proximal end that is proximal to a respective edge of the die pad and a distal end farther from the die pad, and wherein the lead fingers include power bar lead fingers and data carrying lead fingers;
a power bar bridging the proximal ends of two of the power bar lead fingers, wherein the power bar is located between the proximal ends of a group of the data carrying lead fingers and the respective edge of the die pad; and
first insulated bond wires selectively electrically coupling the power bar to a plurality of the die power supply bonding pads.

2. The semiconductor die package of claim 1, further comprising second insulated bond wires selectively electrically coupling the die data bonding pads to the data carrying lead fingers.

3. The semiconductor die package of claim 1, wherein the first insulated bond wires selectively electrically couple the power bar to die power supply bonding pads located along at least two edges of the semiconductor die.

4. The semiconductor die package of claim 1, wherein there is only one said power bar.

5. The semiconductor die package of claim 1, wherein there is a first said power bar and a second said power bar located adjacent the same respective edge of the die pad, and wherein a first plurality of the first insulated bond wires selectively electrically couple the first power bar to the die power supply bonding pads of a first power rating, and a second plurality of the first insulated bond wires selectively electrically couple the second power bar to the die power supply bonding pads of a another power rating.

6. The semiconductor die package of claim 1, further comprising tie bars extending from corner regions of the die pad, wherein at least one of the tie bars has a lead extending therefrom to provide an external ground connection.

7. The semiconductor die package of claim 6, further comprising second insulated bond wires selectively electrically coupling the tie bars to at least two of the die power supply bonding pads.

8. The semiconductor die package of claim 1, further comprising a first said power bar and a second said power bar located adjacent different respective edges of the die pad, and wherein a first plurality of the first insulated bond wires selectively electrically couple the first power bar to the die power supply bonding pads of a first power rating, and a second plurality of the first insulated bond wires selectively electrically couple the second power bar to the die power supply bonding pads of a another power rating.

9. The semiconductor die package of claim 1, further including an encapsulating material covering the semiconductor die and the first insulated bond wires.

10. The semiconductor die package of claim 9, wherein the encapsulating material forms a substantially rectangular housing with edges from which the distal ends of the lead fingers protrude, and wherein the distal ends are bent to form mounting feet.

11. A method of assembling a semiconductor die package, the method comprising:
providing a lead frame that has an outer frame enclosing a centrally located a die pad, tie bars extending from the outer frame and supporting the die pad, a plurality of lead fingers extending from the outer frame towards the die pad, each of the lead fingers having a proximal end that is near to a respective edge of the die pad and a distal end integral with the outer frame, and wherein the lead fingers include power bar lead fingers and data carrying lead fingers, and wherein a power bar bridges the proximal ends of two of the power bar lead fingers so that the power bar is located between the proximal ends of a group of the data carrying lead fingers and one respective edge of the die pad;
mounting a semiconductor die to the die pad, the semiconductor die having a die support mounting surface attached to the die pad and an opposite, active surface having both data bonding pads and power supply bonding pads; and
selectively electrically coupling the power bar to a plurality of the power supply pads with first insulated bond wires.

12. The method of assembling a semiconductor die package of claim 11, further including selectively electrically coupling the data bonding pads to the data carrying lead fingers with second insulated bond wires.

13. The method of assembling a semiconductor die package of claim 11, wherein selectively electrically coupling the power bar includes selectively electrically coupling the power bar to power supply pads located along at least two edges of the semiconductor die with the first insulated bond wires.

14. The method of assembling a semiconductor die package of claim 11, wherein the lead frame has only one said power bar.

15. The method of assembling a semiconductor die package of claim 11, wherein the lead frame includes a first said power bar and a second said power bar, and wherein the first insulated bond wires selectively electrically couple the first power bar to the power supply bonding pads of a first power rating, and second insulated bond wires selectively electrically couple the second power bar to the power supply bonding pads of a another power rating.

16. The method of assembling a semiconductor die package of claim 11, further comprising a lead extending from at least one of the tie bars to provide an external ground connection.

17. The method of assembling a semiconductor die package of claim 16, wherein the selectively electrically coupling includes selectively electrically coupling the tie bars to at least two of the die power supply bonding pads with the first insulated bond wires.

18. The method of assembling a semiconductor die package of claim 11, further including covering the semiconductor die and first insulated bond wires with an encapsulating material.

19. The method of assembling a semiconductor die package of claim 18, further including separating the tie bars and lead fingers from the outer frame.

20. The method of assembling a semiconductor die package of claim 19, further including bending the distal ends of the lead fingers to form mounting feet.
